(19) United States
(12) Patent Application Publication
(10) Pub. No.: US 2013/0077022 A1
(43) Pub. Date: Mar. 28, 2013

(54) ILLUMINATION DEVICE AND METHOD FOR MANUFACTURING THE SAME

(71) Applicant: Junji SANO, Kanagawa-ken (JP)

(72) Inventor: Junji SANO, Kanagawa-ken (JP)

(73) Assignee: KABUSHIKI KAISHA TOSHIBA, Tokyo (JP)

(21) Appl. No.: 13/611,256

(22) Filed: Sep. 12, 2012

(30) Foreign Application Priority Data
Sep. 22, 2011 (JP) 2011-208124

(51) Int. Cl. H01L 51/54; G02F 1/13357; H01L 51/56

(52) U.S. Cl. 349/62; 438/22; 257/99; 257/E51.018

(57) ABSTRACT

According to one embodiment, an illumination device includes a first substrate, a first electrode section, an organic EL section, a second electrode section, and a second substrate. The first electrode section is provided on a surface of the first substrate and including a plurality of openings. The organic EL section is provided so as to cover the first electrode section and the surface of the first substrate exposed to the plurality of openings. The second electrode section is provided so as to cover the organic EL section. The second substrate is opposed to the surface of the first substrate. The first electrode section is an anode, and the second electrode section is a cathode.

### CROSS-REFERENCE TO RELATED APPLICATIONS

This application is based upon and claims the benefit of priority from the prior Japanese Patent Application No.2011-208124, filed on Sep. 22, 2011; the entire contents of which are incorporated herein by reference.

### FIELD

Embodiments described herein relate generally to an illumination device and a method for manufacturing the same.

### BACKGROUND

There is an illumination device based on organic electroluminescence elements (hereinafter simply referred to as organic EL elements).

Such an illumination device can be used, for instance, as a front light device for illuminating a reflection type liquid crystal display device from the front side. Then, the organic EL elements block the reflected light from the reflection type liquid crystal display device.

Thus, miniaturization of organic EL elements is desired.

### BRIEF DESCRIPTION OF THE DRAWINGS

FIG. 1 is a schematic sectional view for illustrating an illumination device 1 according to a first embodiment;

FIG. 2 is a schematic sectional view for illustrating an illumination device 30 according to a comparative example; and

FIGS. 3A to 3E are schematic process sectional views for illustrating a method for manufacturing the illumination device 1 according to a second embodiment.

### DETAILED DESCRIPTION

In general, according to one embodiment, an illumination device includes a first substrate, a first electrode section, an organic EL section, a second electrode section, and a second substrate. The first electrode section is provided on a surface of the first substrate and including a plurality of openings. The organic EL section is provided so as to cover the first electrode section and the surface of the first substrate exposed to the plurality of openings. The second electrode section is provided so as to cover the organic EL section. The second substrate is opposed to the surface of the first substrate. The first electrode section is an anode, and the second electrode section is a cathode.

Various embodiments will be illustrated hereinafter with reference to the accompanying drawings. In the drawings, similar components are labeled with like reference numerals, and the detailed description thereof is omitted appropriately.

### First Embodiment

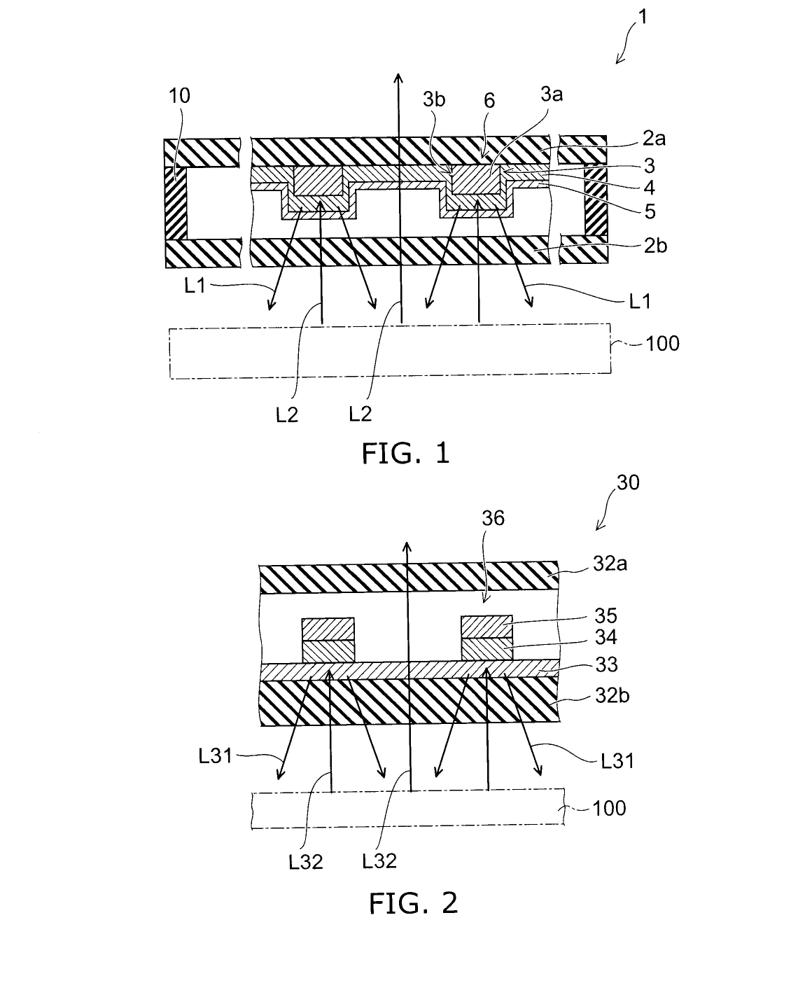

FIG. 1 is a schematic sectional view for illustrating an illumination device 1 according to a first embodiment.

FIG. 2 is a schematic sectional view for illustrating an illumination device 30 according to a comparative example. By way of example, FIGS. 1 and 2 illustrate the case where the illumination device is used as a front light device for illuminating a reflection type liquid crystal display device 100 from the front side.

First, the illumination device 30 according to the comparative example shown in FIG. 2 is illustrated.

As shown in FIG. 2, the illumination device 30 includes a substrate 32a, a substrate 32b, an electrode section 33, an organic EL section 34, and an electrode section 35.

The substrate 32a and the substrate 32b are opposed to each other. The electrode section 33, the organic EL section 34, and the electrode section 35 are provided between the substrate 32a and the substrate 32b.

The electrode section 33 is shaped like a film and is provided on a major surface of the substrate 32b. The electrode section 33 is formed from a translucent conductive material. Hence, the electrode section 33 can transmit light L31 emitted from the organic EL section 34.

The organic EL section 34 has a striped shape extending in a fixed direction (hereinafter simply referred to as striped shape), and is provided on the electrode section 33. The organic EL section 34 can be formed by stacking a hole transport layer, an organic luminescent layer, and an electron transport layer section.

The electrode section 35 has a striped shape and is provided on the organic EL section 34. The electrode section 35 is formed from a metal such as aluminum and silver.

The portion where the electrode section 33, the organic EL section 34, and the electrode section 35 are stacked constitutes an organic EL element 36.

In this case, the electrode section 33 serves as an anode, and the electrode section 35 serves as a cathode.

Thus, a positive potential is applied to the electrode section 33, and a negative potential is applied to the electrode section 35. Then, luminescence occurs in the portion constituting the organic EL element 36. That is, in the organic EL section 34, luminescence occurs in the portion sandwiched between the electrode section 33 and the electrode section 35.

The light L31 emitted from the organic EL section 34 is transmitted through the electrode section 33 and the substrate 32b, and reflected by the reflection type liquid crystal display device 100. The light L32 reflected by the reflection type liquid crystal display device 100 is transmitted through the illumination device 30 and directed to the observer's side. In this case, the electrode section 35 constituting the organic EL element 36 is formed from a metal having a light blocking effect. Hence, part of the light L32 is blocked.

In this case, miniaturization of the organic EL element 36 can reduce the amount of the light L32 blocked.

Here, typically, the organic EL section 34 having a striped shape and the electrode section 35 having a striped shape are formed by using mask vapor deposition.

However, use of mask vapor deposition to form a fine organic EL section 34 and electrode section 35 may cause failures such as the so-called vapor deposition blur and decrease the yield.

Furthermore, forming a fine organic EL section 34 and electrode section 35 requires a high-precision vapor deposition mask, and may increase the manufacturing cost.

Thus, in the configuration of the illumination device 30, miniaturization of the organic EL element 36 is difficult.

Next, returning to FIG. 1, the illumination device 1 according to the first embodiment is illustrated.

As shown in FIG. 1, the illumination device 1 includes a substrate 2a (corresponding to an example of a first substrate), a substrate 2b (corresponding to an example of a second substrate), an electrode section 3 (corresponding to an example of a first electrode section), an organic EL section 4, and an electrode section 5 (corresponding to an example of a second electrode section).

The numeral 100 represents a reflection type liquid crystal display device. The substrate 2a and the substrate 2b can be shaped like a plate formed from a translucent material. The translucent material can be e.g. inorganic glass such as soda lime glass (also referred to as soda glass), quartz, or transparent resin such as polyethylene terephthalate, polypropylene, and polycarbonate.

The substrate 2a and the substrate 2b are opposed to each other. The periphery of the substrate 2a and the periphery of the substrate 2b are sealed with a sealing section 10 made of e.g. frit. The electrode section 3, the organic EL section 4, and the electrode section 5 are provided in the region defined by the sealing section 10. The region defined by the sealing section 10 between the substrate 2a and the substrate 2b can be filled with an inert gas such as nitrogen gas and argon gas.

The electrode section 3 is provided on a major surface of the substrate 2a. The electrode section 3 includes a plurality of openings 3b penetrating in the thickness direction. By including a plurality of openings 3b, the electrode section 3 has a striped shape. The striped portions 3a are provided in a plurality with a prescribed spacing therebetween. The striped portions 3a are provided parallel to each other.

Here, the electrode section 3 serves as an anode. That is, the electrode section 3 serves as an electrode for injecting holes into a hole transport layer provided in the organic EL section 4.

To this end, the electrode section 3 is preferably formed from a material facilitating injecting holes into the hole transport layer.

The material facilitating injecting holes into the hole transport layer can be e.g. a material having a high work function. In this case, preferably, the work function of the material has a value comparable to or larger than the value of the work function of the material forming the organic EL section 4. Typically, the work function of the material forming the organic EL section 4 is approximately 4.8 eV. Thus, from the viewpoint of work function, a material having a work function of 4.7 eV or more is preferable. The material having a work function of 4.7 eV or more can be e.g. a material including at least one selected from the group consisting of gold (Au), palladium (Pd), nickel (Ni), and platinum (Pt).

Furthermore, as described later, part of light L2 reflected by the reflection type liquid crystal display device 100 is incident on the electrode section 3. Thus, the electrode section 3 is preferably formed from a material having a light reflectance of 40% or more in the visible light region. By forming the electrode section 3 from a material having a light reflectance of 40% or more in the visible light region, the amount of light absorbed in the electrode section 3 can be reduced. Thus, the light extraction efficiency can be increased.

As described later, the electrode section 3 can be formed by the dry etching method or wet etching method. Thus, preferably, the material can be easily processed using such processing methods.

Thus, in view of the work function, the light reflectance in the visible light region, and the processing method, the electrode section 3 is preferably formed from a material including at least one selected from the group consisting of palladium, nickel, and platinum.

Here, in view of manufacturing cost and processing difficulty, the electrode section 3 is preferably formed from nickel or nickel alloy.

The organic EL section 4 is shaped like a film. The organic EL section 4 is provided so as to cover the striped portions 3a of the electrode section 3 and the major surface of the substrate 2a exposed to the plurality of openings 3b. The organic EL section 4 can be formed by e.g. stacking a hole transport layer, an organic luminescent layer, and an electron transport layer section. However, the configuration of the organic EL section 4 is not limited thereto, but can be appropriately modified.

The electrode section 5 is shaped like a film. The electrode section 5 is provided so as to cover the organic EL section 4. The electrode section 5 transmits light L1 emitted from the organic EL section 4. To this end, the electrode section 5 is formed from a translucent conductive material. Furthermore, the electrode section 5 is preferably formed from a material having a high light transmittance in the visible light region.

Furthermore, the value of the work function of the electrode section 5 is smaller than the value of the work function of the electrode section 3.

Thus, the electrode section 5 is preferably formed from a material having a work function of less than 4.7 eV and a light transmittance of 30% or more in the visible light region.

For instance, the electrode section 5 can be formed from e.g. ITO (indium tin oxide) or IZO (indium zinc oxide).

In addition, e.g. connection wirings, not shown, for connecting the electrode section 3 and the electrode section 5 to an external power supply can be appropriately provided.

In this embodiment, the portion where the electrode section 3, the organic EL section 4, and the electrode section 5 are stacked constitutes an organic EL element 6.

In this case, the electrode section 3 serves as an anode, and the electrode section 5 serves as a cathode.

Thus, a positive potential is applied to the electrode section 3, and a negative potential is applied to the electrode section 5. Then, luminescence occurs in the portion constituting the organic EL element 6. That is, in the organic EL section 4, luminescence occurs in the portion sandwiched between the electrode section 3 and the electrode section 5.

The illumination device 30 described above emits light through the electrode section 33 serving as an anode. In contrast, the illumination device 1 emits light through the electrode section 5 serving as a cathode.

The light L1 emitted from the organic EL section 4 in the portion constituting the organic EL element 6 is transmitted through the electrode section 5 and the substrate 2b, and reflected by the reflection type liquid crystal display device 100.

The light L2 reflected by the reflection type liquid crystal display device 100 is transmitted through the illumination device 1 and directed to the observer's side. In this case, the electrode section 3 constituting the organic EL element 6 is formed from a metal having a light blocking effect. Hence, part of the light L2 is blocked.

In this case, miniaturization of the organic EL element 6 can reduce the amount of the light L2 blocked.

In this embodiment, of the components constituting the organic EL element 6, it is only the electrode section 3 that needs to be processed into a striped shape. That is, the organic EL section 4 and the electrode section 5 may be left in a film shape.

As described later, this facilitates forming a film 13 constituting the electrode section 3 and processing it into a striped shape using the dry etching method or wet etching method. In this case, the film 13 constituting the electrode section 3 can be processed into a striped shape using the dry etching method or wet etching method used in the so-called semiconductor manufacturing process. Hence, a fine and high-precision electrode section 3 can be easily formed.

This enables miniaturization of the organic EL element 6.

### Second Embodiment

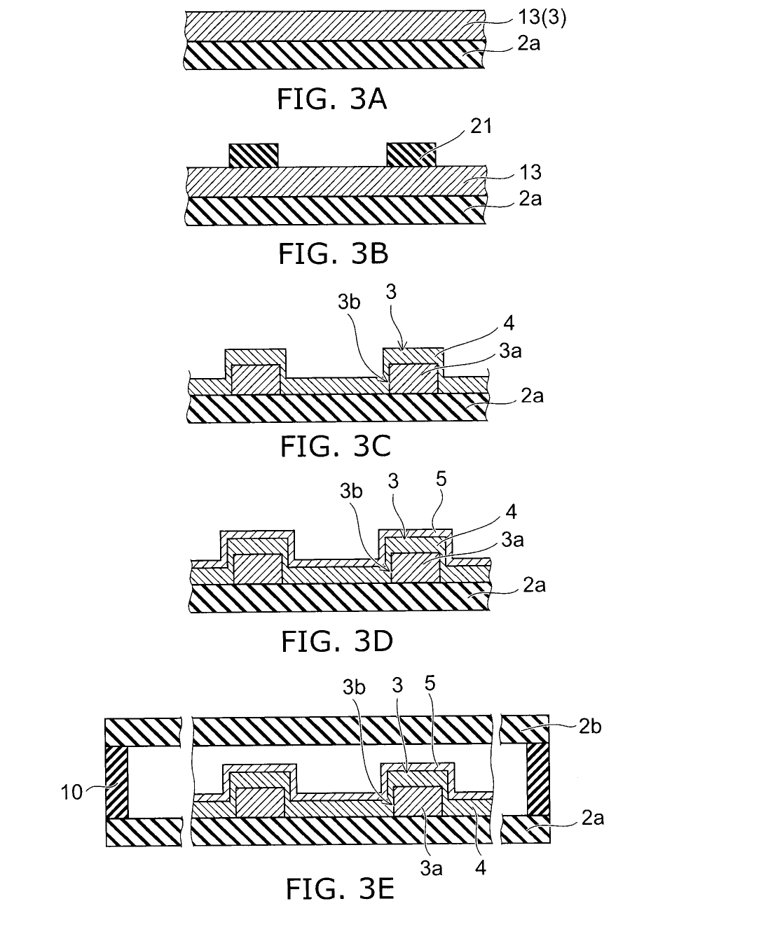

FIGS. 3A to 3E are schematic process sectional views for illustrating a method for manufacturing the illumination device 1 according to a second embodiment.

First, as shown in FIG. 3A, a film 13 constituting an electrode section 3 is formed on a major surface of a substrate 2a formed from a translucent material.

The film 13 constituting the electrode section 3 can be formed by e.g. the sputtering method.

Next, as shown in FIG. 3B, a resist mask 21 having a striped shape is formed on the film 13 constituting the electrode section 3.

For instance, a resist is applied onto the film 13 constituting the electrode section 3. By using the photolithography method, the resist is formed into a resist mask 21 having a striped shape. The portion covered with the resist mask 21 constitutes striped portions 3a.

Next, the electrode section 3 is formed by etching the film 13 using the dry etching method or wet etching method.

For instance, the substrate 2a can be formed from inorganic glass, and the film 13 constituting the electrode section 3 can be formed from nickel. In this case, the electrode section 3 can be formed by etching the film 13 with an etching liquid containing ferric chloride (FeCl₃).

In forming the electrode section 3, connection wirings, not shown, for connecting the electrode section 3 and the electrode section 5 to an external power supply can be appropriately formed.

Next, the resist mask 21 is removed.

The resist mask 21 can be removed using e.g. the dry ashing method with oxygen plasma or the wet ashing method with organic solvent.

Next, as shown in FIG. 3C, a film-shaped organic EL section 4 is formed.

The organic EL section 4 is formed so as to cover the striped portions 3a of the electrode section 3 and the major surface of the substrate 2a exposed to the plurality of openings 3b.

For instance, the film-shaped organic EL section 4 can be formed by applying a known luminescent material dissolved in organic solvent using e.g. the ink jet method, nozzle application method, dispenser method, or screen printing method.

Next, as shown in FIG. 3D, a film-shaped electrode section 5 is formed so as to cover the organic EL section 4.

The electrode section 5 can be formed using e.g. physical vapor deposition (PVD) such as the sputtering method, or chemical vapor deposition (CVD).

For instance, the film-shaped electrode section 5 can be formed by forming a film made of ITO on the organic EL section 4 using the sputtering method.

In this case, the portion where the electrode section 3, the organic EL section 4, and the electrode section 5 are stacked constitutes an organic EL element 6.

Next, as shown in FIG. 3E, the substrate 2a and the substrate 2b are opposed to each other. The periphery of the substrate 2a and the periphery of the substrate 2b are sealed with e.g. frit.

For instance, on the periphery of the substrate 2b, frit is applied in a prescribed shape and baked. Then, in an inert gas atmosphere such as nitrogen gas and argon gas, the substrate 2a with the electrode section 3, the organic EL section 4, and the electrode section 5 formed thereon is stacked with the substrate 2b on which the baked frit is formed. Next, the baked frit is irradiated with laser. Thus, the frit is melted and solidified. Hence, the periphery of the substrate 2a and the periphery of the substrate 2b are sealed together. In this case, a sealing section 10 is formed by melting and solidifying the frit.

Thus, the illumination device 1 can be manufactured.

In the method for manufacturing the illumination device 1 according to this embodiment, the film 13 constituting the electrode section 3 is etched into a striped shape using the dry etching method or wet etching method used in the so-called semiconductor manufacturing process. Hence, a fine and high-precision electrode section 3 can be easily formed. In this case, the organic EL section 4 and the electrode section 5 are left in a film shape.

Thus, the illumination device 1 including the miniaturized organic EL element 6 can be easily manufactured.

In the illumination device 1 and the method for manufacturing the illumination device 1 illustrated above, the electrode section 3 having a striped shape is provided. However, the shape of the electrode section 3 is not limited to a striped shape. For instance, the electrode section 3 can also be shaped like a lattice.

That is, the electrode section 3 only needs to include a plurality of openings penetrating in the thickness direction. In this case, by including a plurality of openings, the electrode section 3 has at least one of a striped shape extending in a fixed direction, and a lattice shape.

However, in the case where the illumination device 1 is used as a front light device for illuminating a reflection type liquid crystal display device 100 from the front side, it is preferable to use a striped shape in which the transmission of the reflected light L2 is less likely to be suppressed.

The arrangement spacing (arrangement pitch dimension) in the striped shape or lattice shape may be fixed or varied. The width dimension in the striped shape or lattice shape may be fixed or varied.

According to the embodiments illustrated hereinabove, an illumination device and a method for manufacturing the same that can achieve miniaturization of the organic EL element can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Moreover, above-mentioned embodiments can be combined mutually and can be carried out.

What is claimed is:

1. An illumination device comprising:
a first substrate;
a first electrode section provided on a surface of the first substrate and including a plurality of openings;
an organic EL section provided so as to cover the first electrode section and the surface of the first substrate exposed to the plurality of openings;
a second electrode section provided so as to cover the organic EL section; and
a second substrate opposed to the surface of the first substrate,
the first electrode section being an anode, and the second electrode section being a cathode.

2. The device according to claim 1, wherein the first electrode section has a work function of 4.7 eV or more.

3. The device according to claim 1, wherein the first electrode section has a light reflectance of 40% or more in a visible light region.

4. The device according to claim 1, wherein the first electrode section includes at least one selected from the group consisting of palladium, nickel, and platinum.

5. The device according to claim 1, wherein the second electrode section has a smaller value of work function than the first electrode section.

6. The device according to claim 1, wherein the second electrode section has a work function of less than 4.7 eV.

7. The device according to claim 1, wherein the second electrode section has a light transmittance of 30% or more in a visible light region.

8. The device according to claim 1, wherein the second electrode section includes at least one of ITO (indium tin oxide) and IZO (indium zinc oxide).

9. The device according to claim 1, wherein the first electrode section has at least one of a striped shape extending in a fixed direction and a lattice shape by including the plurality of openings.

10. The device according to claim 1, wherein the second electrode section is shaped like a film.

11. The device according to claim 1, wherein the organic EL section is shaped like a film.

12. The device according to claim 1, wherein
the first electrode section,
the second electrode section, and
a portion of the organic EL section sandwiched between the first electrode section and the second electrode section constitute an organic EL element.

13. The device according to claim 1, wherein light generated in a portion of the organic EL section sandwiched between the first electrode section and the second electrode section is emitted through the second electrode section.

14. The device according to claim 13, wherein
the light emitted through the second electrode section is reflected by a reflection type liquid crystal display device, and
the light reflected by the reflection type liquid crystal display device is transmitted through the second electrode section and the organic EL section.

15. A method for manufacturing an illumination device, comprising:
forming a film constituting a first electrode section on a surface of a first substrate;
forming the first electrode section including a plurality of openings by etching the film constituting the first electrode section;
forming an organic EL section so as to cover the first electrode section and the surface of the first substrate exposed to the plurality of openings;
forming a second electrode section so as to cover the organic EL section; and
opposing a second substrate to the surface of the first substrate and forming a sealing section sealing a periphery of the first substrate and a periphery of the second substrate.

16. The method according to claim 15, wherein the forming the first electrode section including a plurality of openings by etching the film constituting the first electrode section includes:
forming the first electrode section including a plurality of openings by using an etching liquid containing ferric chloride.

17. The method according to claim 15, wherein the forming an organic EL section so as to cover the first electrode section and the surface of the first substrate exposed to the plurality of openings includes:
forming the organic EL section shaped like a film by applying a luminescent material dissolved in an organic solvent.

18. The method according to claim 15, wherein the forming a second electrode section so as to cover the organic EL section includes:
forming the second electrode section shaped like a film by using physical vapor deposition or chemical vapor deposition.

19. The method according to claim 15, wherein the opposing the second substrate to the surface of the first substrate and forming a sealing section sealing a periphery of the first substrate and a periphery of the second substrate includes:
opposing the second substrate to the surface of the first substrate in an inert gas atmosphere.

20. The method according to claim 15, wherein the first electrode section includes at least one selected from the group consisting of palladium, nickel, and platinum.
